(19) United States
(12) Patent Application Publication
(10) Pub. No.: US 2011/0044004 A1
(43) Pub. Date: Feb. 24, 2011

(54) HEAT TRANSFER APPARATUS HAVING A THERMAL INTERFACE MATERIAL

(76) Inventors: Thomas J. Garosshen, Glastonbury, CT (US); Joseph V. Mantese, Ellington, CT (US)

Correspondence Address: CARLSON, GASKEY & OLDS, P.C., 400 WEST MAPLE ROAD, SUITE 350, BIRMINGHAM, MI, 48009, US

(21) Appl. No.: 12/542,744

(22) Filed: Aug. 18, 2009

(51) Int. Cl. H05K 7/20; F28F 21/00

(52) U.S. Cl. 361/709; 165/185

(57) ABSTRACT

A heat-transfer apparatus includes a heat-producing body, a heat sink adjacent to the heat-producing body, and a thermal interface material that includes a plurality of heat-transfer particles bridging the heat-producing body and the heat sink.

### BACKGROUND OF THE INVENTION

This disclosure relates to thermal interface materials for cooling heat-producing devices, such as electronic devices. Electronic devices and the like typically produce heat during operation. The heat may be removed using a heat sink or similar cooling scheme to maintain the device at a suitable operating temperature. However, as power densities increase, the amount of heat produced also increases and transferring increased amounts of heat presents several challenges. For instance, heating cycles can cause thermal stresses between the device and the heat sink, and the device must be electrically isolated to prevent electric arcing.

### SUMMARY OF THE INVENTION

An exemplary heat-transfer apparatus includes a heat-producing body, a heat sink adjacent to the heat-producing body, and a thermal interface material that includes a plurality of heat-transfer particles bridging the heat-producing body and the heat sink.

An exemplary method for transferring heat includes operating a heat producing body to produce heat and transferring the heat to a heat sink located adjacent to the heat-producing body through a thermal interface material that includes a plurality of heat transfer particles bridging the heat-producing body and the heat sink.

An exemplary thermal interface material includes a polymer film having first and second sides, and a plurality of heat transfer particles bridging the first and second sides.

### BRIEF DESCRIPTION OF THE DRAWINGS

The various features and advantages of the disclosed examples will become apparent to those skilled in the art from the following detailed description. The drawings that accompany the detailed description can be briefly described as follows.

FIG. 1 illustrates an example heat-transfer apparatus.

FIG. 2 illustrates an example thermal interface material.

FIG. 3 illustrates another thermal interface material.

FIG. 4 illustrates another example heat-transfer apparatus.

### DETAILED DESCRIPTION OF THE PREFERRED EMBODIMENT

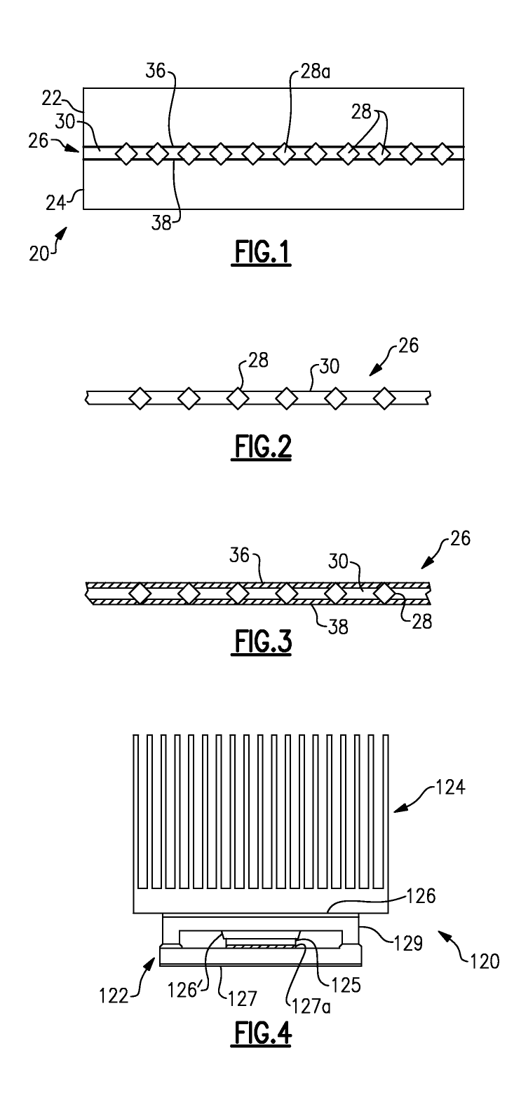

FIG. 1 illustrates selected portions of an example heat-transfer apparatus 20. In this example, the heat transfer apparatus 20 includes a heat-producing body 22 and a heat sink 24 for facilitating removal of heat from the heat-producing body 22. As an example, the heat-producing body 22 may be an electronic device or other such device that produces heat during operation. In this case, the heat sink 24 removes waste heat from the heat-producing body 22 to maintain the heat-producing body 22 at a desirable operating temperature.

The heat transfer apparatus 20 includes a thermal interface material 26 between the heat-producing body 22 and the heat sink 24 for facilitating heat-transfer therebetween. In the illustrated example, the thermal interface material 26 includes a plurality of heat-transfer particles 28 that bridge the heat-producing body 22 and the heat sink 24. That is, the individual particles 28 span entirely between the heat-producing body 22 and the heat sink 24. In one example, one of the particles 28, such as particle 28a, is partially embedded into the heat-producing body 22 and is also partially embedded into the heat sink 24. Thus, the heat-transfer particles 28 are in intimate contact with each of the heat-producing body 22 and the heat sink 24 to facilitate heat transfer.

The heat-transfer particles 28 are made of a high thermal conductive material. For instance, the heat-transfer particles 28 may be ceramic particles that provide a relatively high thermal conductivity but also provide suitable dielectric strength for preventing electric arcing between the heat-producing body 22 and the heat sink 24. In some examples, the heat-transfer particles 28 may be diamond particles, aluminum nitride particles (AlN), silicon carbide particles (SiC), boron nitride particles (BN), silicon nitride particles (Si₃N₄), or combinations thereof. Given this description, one of ordinary skill in the art will also recognize other types of ceramic particles that may be used for the heat-transfer particles 28 to provide a desirable level of thermal conductivity and dielectric strength.

The thermal interface material 26 may also include a polymer film 30 for facilitating bonding the heat-producing body 22 and the heat sink 24 together. As an example, the polymer film 30 may be polyimide, epoxy, acrylic, or combinations thereof. Given this description, one of ordinary skill in the art will recognize other types of polymer films to suit their particular needs. Additionally, the polymer film 30 also has a relatively high dielectric strength to further facilitate prevention of electric arcing.

In some examples, the heat transfer apparatus 20 may further include a first metal film 36 between the thermal interface material 26 and the heat-producing body 22, and a second metal film 38 between the thermal interface material 26 and the heat sink 24. The first and second metal films 36 and 38 may facilitate heat transfer between the thermal interface material and either of the heat-producing body 22 and the heat sink 24. As an example, the first and second metal films 36 and 38 may be copper, aluminum, silver, gold, nickel, or combinations thereof. The metal films 36 and 38 may be pure or relatively pure metals, or alloys with a base metal of copper, aluminum, silver, gold, or nickel.

The heat-transfer particles 28 may have an average particle size that facilitates bridging the heat-producing body 22 and the heat sink 24. For example, the average particle size may be about 1-100 micrometers. If the particles are too small, the particles may become completely embedded within the polymer film 30 and there may be difficulty in bridging the heat-producing body 22 and the heat sink 24. Additionally, the polymer film 30 would have to be very thin and may be difficult to process. If the particles are very large, the functionality of the polymer film 30 is reduced and the thermal interface material 26 behaves more like a solid substrate.

FIG. 2 illustrates an isolated view of the thermal interface material 26. The thermal interface material 26 may be provided as a prefabricated component that is then assembled between the heat-producing body 22 and the heat sink 24. In this regard, the thermal interface material 26 may be provided in sheet form, on a roll (tape), or in a similar suitable form for assembly. The surfaces of the heat-producing body 22 and the heat seat 24 may be coated with the first and second metal films 36 and 38 prior to assembly of the thermal interface material 26.

FIG. 3 illustrates the thermal interface material 26 in another prefabricated form, but with the first and second metal films 36 and 38 applied onto the respective top and bottom surfaces. The thermal interface material 26 may be provided as a prefabricated sheet or as a roll (tape) for assembly between the heat-producing body 22 and the heat sink 24.

In other examples, the thermal interface material 26 may be formed directly between the heat-producing body 22 and the heat sink 24. For instance, the heat transfer particles 28 may be deposited onto either of the surfaces of the heat-producing body 22 or the heat sink 24 and pressed to partially embed the particles 28. The polymer film 30 may then be deposited onto the particles 28 before pressing the heat-producing body 22 and the heat sink 24 together. The first and second metal films 36 and 38 may be pre-deposited onto the surfaces of the heat-producing body 22 and the heat sink 24.

FIG. 4 illustrates an example implementation of a thermal interface material 126. In this disclosure, like reference numerals designate like elements where appropriate, and reference numerals with the addition of one-hundred or multiples thereof designate modified elements that are understood to incorporate the same features and benefits of the corresponding original elements.

In this example, the heat transfer apparatus 120 includes an electronic device 122 and an adjacent heat sink 124 for dissipating heat produced by the electronic device 122. The electronic device 122 includes a microchip 125 mounted on a substrate 127 in a known manner. A cover 129 seals the microchip 125 from the surrounding environment. A first thermal interface material 126 is located between the cover 129 and the heat sink 124. As described above, the thermal interface material 126 facilitates heat-transfer between the electronic device 122 and the heat sink 124.

Additionally, the electronic device 122 includes another thermal interface material 126′ between the inside surface of the cover 129 and the microchip 125. In this case, the thermal interface material 126′ receives the heat directly from the microchip 125 and dissipates that heat to the cover 129, which spreads the heat over a larger area for dissipation through the thermal interface material 126 to the heat sink 124. In this regard, the cover 129 may be considered to be a heat sink.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from the essence of this disclosure. The scope of legal protection given to this disclosure can only be determined by studying the following claims.

What is claimed is:

1. A heat-transfer apparatus comprising:
a heat-producing body;
a heat sink adjacent to the heat-producing body; and
a thermal interface material including a plurality of heat-transfer particles bridging the heat-producing body and the heat sink.

2. The heat-transfer apparatus as recited in claim 1, wherein the heat-transfer particles are ceramic particles.

3. The heat-transfer apparatus as recited in claim 1, wherein the heat-transfer particles are selected from a group consisting of diamond particles, aluminum nitride particles, silicon carbide particles, boron nitride particles, silicon nitride particles, and combinations thereof.

4. The heat-transfer apparatus as recited in claim 1, wherein the thermal interface material further includes a polymer film between the heat-producing body and the heat sink, and the heat-transfer particles are partially embedded within the polymer film.

5. The heat-transfer apparatus as recited in claim 4, wherein the polymer film is selected from a group consisting of polyimide, epoxy, acrylic, and combinations thereof.

6. The heat-transfer apparatus as recited in claim 1, wherein the plurality of heat transfer particles are partially embedded within the heat-producing body and partially embedded within the heat sink.

7. The heat-transfer apparatus as recited in claim 1, further comprising a first metal film between the thermal interface material and the heat-producing body, and a second metal film between the thermal interface material and the heat sink.

8. The heat-transfer apparatus as recited in claim 7, wherein each of the first metal film and the second metal film is selected from a group consisting of copper, aluminum, silver, gold, nickel, and combinations thereof.

9. The heat-transfer apparatus as recited in claim 1, wherein the plurality of heat transfer particles have an average particle size of about 1-100 micrometers.

10. The heat-transfer apparatus as recited in claim 1, wherein the heat-producing body is an electronic device.

11. A method for transferring heat, comprising:
operating a heat-producing body to produce heat; and
transferring the heat to a heat sink located adjacent to the heat-producing body through a thermal interface material having a plurality of heat-transfer particles bridging the heat-producing body and the heat sink.

12. The method as recited in claim 11, including selecting the plurality of heat-transfer particles to be ceramic particles.

13. The method as recited in claim 11, including selecting the plurality of heat-transfer particles from a group consisting of diamond particles, aluminum nitride particles, silicon carbide particles, boron nitride particles, silicon nitride particles, and combinations thereof.

14. The method as recited in claim 11, wherein the thermal interface material includes a polymer film, and selecting the polymer film from a group consisting of polyimide, epoxy, acrylic, and combinations thereof.

15. The method as recited in claim 11, further comprising transferring the heat through first and second metal films located on respective sides of the thermal interface material, and selecting the first and second metal films from a group consisting of copper, aluminum, silver, gold, nickel, and combinations thereof.

16. A thermal interface material comprising:
a polymer film having first and second sides; and
a plurality of heat-transfer particles bridging the first and second sides.

17. The thermal interface material as recited in claim 16, wherein the plurality of heat transfer particles are ceramic particles.

18. The thermal interface material as recited in claim 16, wherein the plurality of heat transfer particles are selected from a group consisting of diamond particles, aluminum nitride particles, silicon carbide particles, boron nitride particles, silicon nitride particles, and combinations thereof.

19. The thermal interface material as recited in claim 16, wherein the polymer film is selected from a group consisting of polyimide, epoxy, acrylic and combinations thereof.

20. The thermal interface material as recited in claim 16, further comprising a first metal film on the first side of the polymer film, and a second metal film on the second side of the polymer film, and the first metal film and the second metal film are selected from a group consisting of copper, aluminum, silver, gold, nickel, and combinations thereof.
